(19) United States
(12) Patent Application Publication
(10) Pub. No.: US 2026/0359544 A1
(43) Pub. Date: Nov. 12, 2026

(54) SEMICONDUCTOR DEVICE AND METHOD OF DESIGNING THE SAME

(71) Applicant: Renesas Electronics Corporation, Tokyo (JP)

(72) Inventor: Shunichi TOKUDA, Tokyo (JP)

(21) Appl. No.: 19/630,609

(22) Filed: Mar. 27, 2026

(30) Foreign Application Priority Data
May 9, 2025 (JP) 2025-078561

(51) Int. Cl. G06F 30/392

(52) U.S. Cl. CPC G06F 30/392

(57) ABSTRACT

A semiconductor device according to one embodiment includes cell tracks in which standard cells are arranged in a width direction, and is configured with a standard cell group in which a width of standard cells arranged in a second region defined on an outer side of a semiconductor chip in the width direction of the cell tracks are designed to be narrower than a width of standard cells arranged in a first region defined on an inner side of the semiconductor chip.

### CROSS-REFERENCE TO RELATED APPLICATIONS

The disclosure of Japanese Patent Application No. 2025-078561 filed on May 9, 2025 including the specification, drawings and abstract is incorporated herein by reference in its entirety.

### BACKGROUND

The present disclosure relates to a semiconductor device and a method of designing the same, and particularly to a semiconductor device designed by arranging a plurality of standard cells each having a predetermined height, and a method of designing the same.

The following technique is known.

Patent Document 1 Japanese Unexamined Patent Application Publication No. 2001-176980

One of the design methods for a semiconductor device is automatic placement and routing in which placement of elements and routing are performed using standard cells whose element shapes have been determined. Patent Document 1 discloses a technology related to this automatic placement and routing.

A design support system disclosed in Patent Document 1 includes a cell library having a plurality of logic cells, a plurality of power supply cells having different heights, different numbers of power supply lines, or different allowable current values, and a plurality of ground cells having different heights, different numbers of ground lines, or different allowable current values, and a placement tool that individually controls placement of the logic cells, the power supply cells, and the ground cells.

### SUMMARY

In a semiconductor device designed using the design support system disclosed in Patent Document 1, area utilization efficiency on a semiconductor chip is improved by sharing a power supply wiring or a ground wiring between adjacent cell tracks. However, in the technique described in Patent Document 1, an area in a width direction in which standard cells are arranged cannot be reduced, and thus there is a problem that area utilization efficiency of the semiconductor chip cannot be sufficiently improved.

Other problems and novel features will become apparent from the description of the present specification and the accompanying drawings.

A semiconductor device and a method of designing the same according to one embodiment include cell tracks in which standard cells are arranged in a width direction, and are configured with a standard cell group in which a width of standard cells arranged in a second region defined on an outer side of a semiconductor chip in the width direction of the cell tracks is designed to be narrower than a width of standard cells arranged in a first region defined on an inner side of the semiconductor chip.

According to a semiconductor device and a method of designing the same according to one embodiment, area utilization efficiency of a semiconductor chip can be sufficiently improved.

### BRIEF DESCRIPTION OF THE DRAWINGS

FIG. 1 is a schematic diagram of a semiconductor device according to a first embodiment.

FIG. 2 is a diagram illustrating shapes of standard cells employed in the semiconductor device according to the first embodiment.

FIG. 3 is a diagram illustrating sizes of cell tracks arranged in the semiconductor device according to the first embodiment.

FIG. 4 is a block diagram of a design support system used for designing the semiconductor device according to the first embodiment.

FIG. 5 is a flowchart illustrating a procedure of a method of designing the semiconductor device using the design support system according to the first embodiment.

### DETAILED DESCRIPTION

### First Embodiment

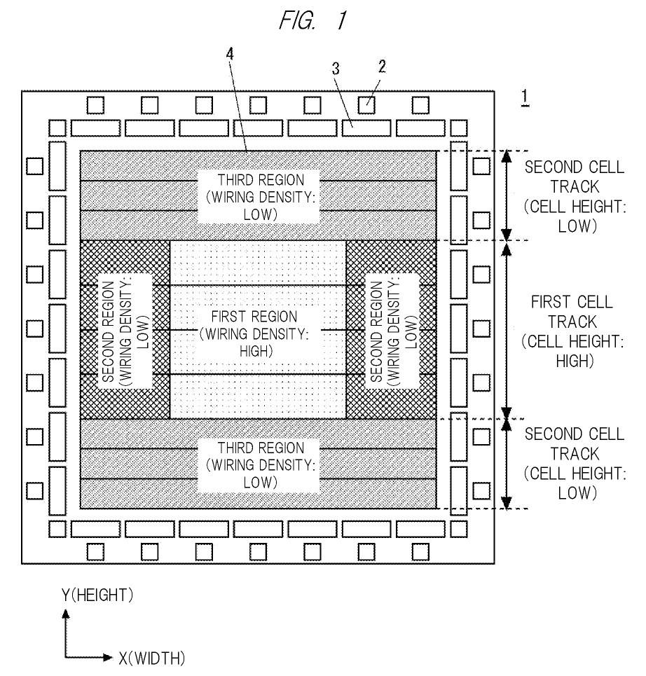

Hereinafter, an embodiment of the present invention will be described with reference to the drawings. First, FIG. 1 illustrates a schematic diagram of a semiconductor device according to the first embodiment. FIG. 1 is a schematic diagram of a semiconductor chip 1 accommodated in a package of the semiconductor device.

As illustrated in FIG. 1, the semiconductor chip 1 according to the first embodiment includes external pads 2, input/output terminal circuits 3, and an element placement region 4. The external pads 2 are arranged along sides of the semiconductor chip 1. In an example illustrated in FIG. 1, a plurality of the external pads 2 is arranged along four sides of the semiconductor chip 1; however, the external pads 2 may be provided, for example, only on two opposing sides. That is, the number of sides on which the external pads 2 is arranged is determined according to specifications of the semiconductor chip 1.

Further, the semiconductor chip 1 is provided with the input/output terminal circuits 3 corresponding to the external pads 2. The input/output terminal circuits 3 are provided closer to an inside of the semiconductor chip 1 than the external pads 2 and in a vicinity of the external pads 2. The input/output terminal circuits 3 include, for example, an electrostatic discharge protection element used for electrostatic discharge protection.

In the semiconductor chip 1, the element placement region 4 is provided in a region interposed between the external pads 2 or surrounded by the external pads 2. In the example illustrated in FIG. 1, the element placement region 4 is set closer to the inside than positions where the input/output terminal circuits 3 are arranged. A plurality of cell tracks is set in the element placement region 4.

Hereinafter, in the following description, in each cell track, a first direction X in which standard cells having predetermined shapes are arranged in advance is referred to as a width direction. Further, in the element placement region 4, a second direction Y in which the cell tracks are arranged and which is orthogonal to the width direction is referred to as a height direction. A standard cell is a circuit of one layout unit and includes circuit elements that constitute a predetermined logic circuit.

In each cell track, a plurality of standard cells is arranged in the width direction. In the semiconductor chip 1, wiring density tends to increase toward a central portion of the semiconductor chip and tends to decrease in a peripheral portion. Accordingly, in the semiconductor chip 1 according to the first embodiment, two types of cell tracks having different heights are used. In the example illustrated in FIG. 1, first cell tracks having a larger height are arranged in a portion including a central portion of the semiconductor chip 1, and second cell tracks having a smaller height are arranged in portions closer to an outer periphery of the semiconductor chip 1. Although specific details will be described later, a group of standard cells arranged in the second cell tracks is obtained by reducing a height of a wiring region of a group of standard cells arranged in the first cell tracks. A region in which the second cell tracks are arranged is also referred to as a third region in the following description.

Further, in the semiconductor chip 1 according to the first embodiment, a first region including a center point of the semiconductor chip 1 among the first cell tracks and a second region including a region on an outer peripheral side of the semiconductor chip 1 relative to the first region are defined. Then, by arranging standard cells having different shapes from the first region to the third region, a chip area of the semiconductor chip 1 according to the first embodiment is reduced or an area utilization efficiency of the chip area is improved.

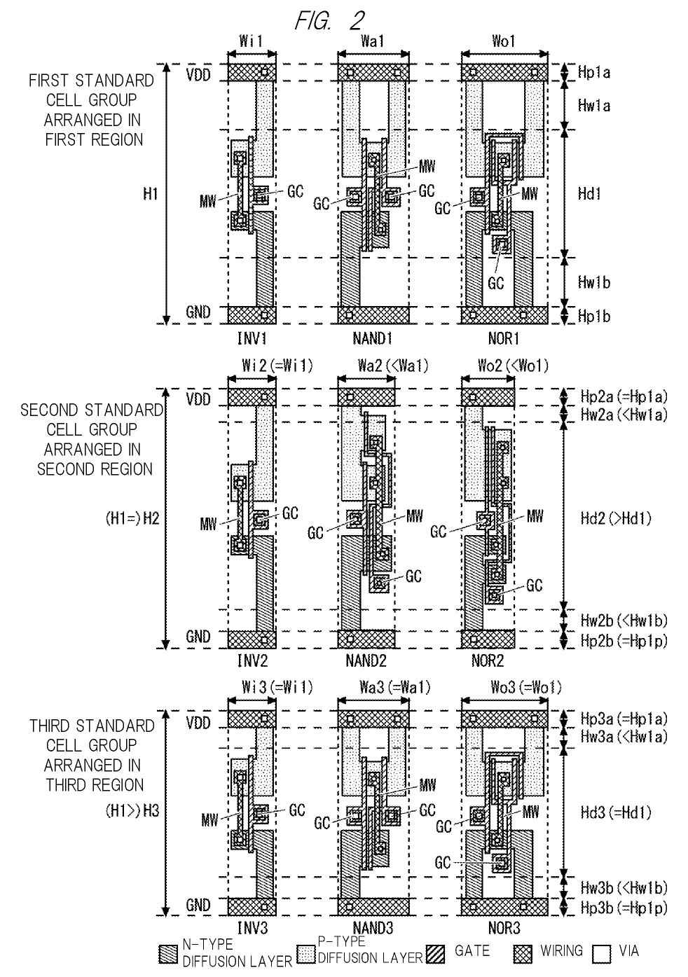

Next, details of the standard cells arranged in the semiconductor chip 1 according to the first embodiment will be described. FIG. 2 is a diagram illustrating shapes of standard cells employed in the semiconductor device according to the first embodiment. FIG. 2 illustrates a standard cell included in a first standard cell group arranged in the first region, a standard cell included in a second standard cell group arranged in the second region, and a standard cell included in a third standard cell group arranged in the third region. Further, each standard cell group illustrates standard cells that operate according to the same logic. Specifically, FIG. 2 illustrates three standard cells: an inverter circuit, a NOR circuit, and an inverted AND circuit.

First, a height H2 and a width Wi2 of an inverter circuit INV2 of the second standard cell group are set to be equal to a height H1 and a width Wi1 of an inverter circuit INV1 of the first standard cell group. A height H3 of an inverter circuit INV3 of the third standard cell group is set to be lower than the height H1 of the inverter circuit INV1 of the first standard cell group. A width Wi3 of the inverter circuit INV3 of the third standard cell group is set to be equal to the width Wi1 of the inverter circuit INV1 of the first standard cell group.

A height H2 of an inverted AND circuit NAND2 of the second standard cell group is set to be equal to a height H1 of an inverted AND circuit NAND1 of the first standard cell group. A width Wa2 of the inverted AND circuit NAND2 of the second standard cell group is set to be narrower than a width Wa1 of the inverted AND circuit NAND1 of the first standard cell group. A height H3 of an inverted AND circuit NAND3 of the third standard cell group is set to be lower than the height H1 of the inverted AND circuit NAND1 of the first standard cell group. A width Wa3 of the inverted AND circuit NAND3 of the third standard cell group is set to be equal to the width Wa1 of the inverted AND circuit NAND1 of the first standard cell group.

A height H2 of an inverted OR circuit NOR2 of the second standard cell group is set to be equal to a height H1 of an inverted OR circuit NOR1 of the first standard cell group. A width Wo2 of the inverted OR circuit NOR2 of the second standard cell group is set to be narrower than a width Wo1 of the inverted OR circuit NOR1 of the first standard cell group. A height H3 of an inverted OR circuit NOR3 of the third standard cell group is set to be lower than the height H1 of the inverted OR circuit NOR1 of the first standard cell group. A width Wo3 of the inverted OR circuit NOR3 of the third standard cell group is set to be equal to the width Wo1 of the inverted OR circuit NOR1 of the first standard cell group.

Further, each standard cell has an element region, a wiring region, a power supply wiring portion, and a ground wiring portion. Specifically, the element region includes a gate contact GC that connects a gate of a Metal-Oxide-Semiconductor (MOS) transistor serving as a circuit element to a wiring arranged in a lowest wiring layer, and an intra-cell inter-element wiring MW that connects elements arranged within the standard cell and that is arranged in the lowest wiring layer. On the other hand, the wiring region does not include the gate contact GC and the intra-cell inter-element wiring MW. The wiring region is a region that is arranged in the lowest wiring layer and is defined as an arrangement region for the inter-cell wiring that connects different standard cells. The power supply wiring portion is arranged at an uppermost side in the height direction. The ground wiring portion is arranged at a lowermost side in the height direction. In the standard cell, two wiring regions are arranged so as to interpose the element region in a region interposed between the ground wiring portion and the power supply wiring portion.

As illustrated in FIG. 2, a height Hd2 of the element region of a standard cell included in the second standard cell group is higher than a height Hd1 of the element region of a standard cell included in the first standard cell group. On the other hand, heights Hw2a and Hw2b of the wiring region of a standard cell included in the second standard cell group are lower than heights Hw1a and Hw1b of the wiring region of a standard cell included in the first standard cell group.

A height Hd3 of an element region of a standard cell included in the third standard cell group is equal to a height Hd1 of an element region of a standard cell included in the first standard cell group. On the other hand, heights Hw3a and Hw3b of wiring regions of a standard cell included in the third standard cell group are lower than heights Hw1a and Hw1b of wiring regions of a standard cell included in the first standard cell group.

A height of the power supply wiring portion is set to be equal among the first standard cell group to the third standard cell group (Hp1a = Hp2a = Hp3a). A height of the ground wiring portion is set to be equal among the first standard cell group to the third standard cell group (Hp1b = Hp2b = Hp3b).

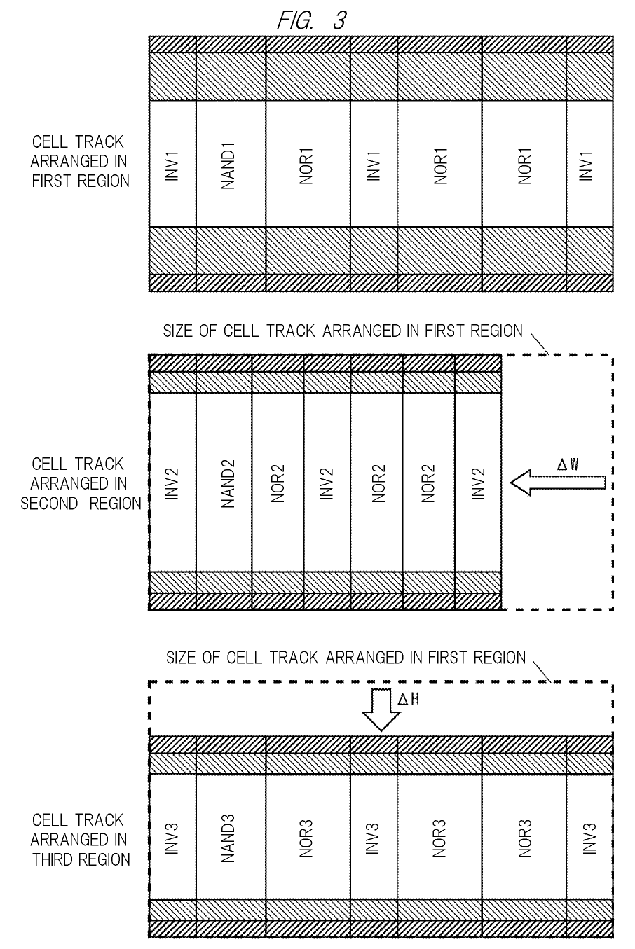

Next, an area of the first region to the third region when the standard cells illustrated in FIG. 2 are arranged will be described. FIG. 3 is a diagram illustrating a size of cell tracks arranged in the semiconductor device according to the first embodiment. In the example illustrated in FIG. 3, a plurality of standard cells are arranged in the first region to the third region so as to form the same logic circuit.

As illustrated in FIG. 3, with respect to the second region, an overall width is smaller than a width of the first region by ΔW, while a height is the same. Further, with respect to the third region, a height is lower than that of the first region by ΔH, while a width is the same.

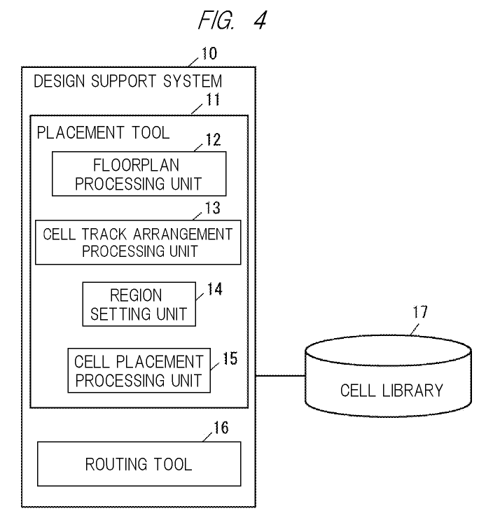

Here, design of the semiconductor chip 1 according to the first embodiment can be performed, for example, using a design support system that executes an autonomous placement and routing program on a computer. Accordingly, FIG. 4 illustrates a block diagram of a design support system 10 used for designing the semiconductor device according to the first embodiment.

As illustrated in FIG. 4, the design support system 10 according to the first embodiment includes a placement tool 11 and a routing tool 16. A cell library 17 is a storage device that stores information of standard cells used in the design support system 10, and may be incorporated in the design support system 10 or may be arranged at a location different from the design support system 10.

The placement tool 11 and the routing tool 16 are functional blocks implemented by executing an autonomous placement and routing program on a computer. The placement tool 11 includes a floorplan processing unit 12, a cell track arrangement processing unit 13, a region setting unit 14, and a cell placement processing unit 15.

The floorplan processing unit 12 executes floorplan processing for arranging external pads arranged along sides of a semiconductor chip and arranging an element placement region in a region interposed between the external pads. The cell track arrangement processing unit 13 executes cell track arrangement processing for arranging, in the element placement region, a plurality of first cell tracks in a height direction, in which standard cells having a first height are arranged in a width direction defined as a first direction. Further, in the cell track arrangement processing, the cell track arrangement processing unit 13 arranges second cell tracks in the height direction in addition to the first cell tracks.

The region setting unit 14 executes region setting processing for setting a first region including a center point of the semiconductor chip and a second region including a region on an outer peripheral side of the semiconductor chip relative to the first region. Further, in the region setting processing, the region setting unit 14 sets a third region in a region in which the second cell tracks are arranged.

The cell placement processing unit 15 executes cell placement processing for arranging a first standard cell group including a plurality of standard cells that operate according to different logics in the first region and arranging, in the second region, a second standard cell group including at least one standard cell that operates according to the same logic as a standard cell included in the first standard cell group and that has a width narrower than that of the standard cell included in the first standard cell group. Further, in the cell placement processing, the cell placement processing unit 15 arranges, in the third region, a third standard cell group having a height lower than that of the standard cell included in the first standard cell group.

The routing tool 16 performs routing processing for connecting standard cells arranged in the cell placement processing.

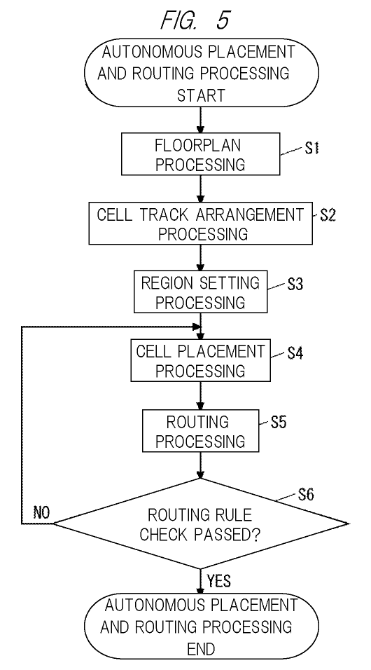

Next, a flow of designing the semiconductor chip 1 using the design support system 10 will be described. Accordingly, FIG. 5 illustrates a flowchart illustrating a procedure of a method of designing the semiconductor device using the design support system according to the first embodiment.

As illustrated in FIG. 5, the design support system 10 first executes floorplan processing by the floorplan processing unit 12 (Step S1). Subsequently, the cell track arrangement processing unit 13 executes cell track arrangement processing (Step S2). Thereafter, the region setting unit 14 executes region setting processing for setting the first region to the third region (Step S3).

Next, the cell placement processing unit 15 executes cell placement processing (Step S4), and the routing tool 16 executes routing processing (Step S5). Thereafter, the design support system 10 executes a routing rule check to check whether wiring arranged in the routing processing (Step S5) satisfies predefined routing rules, and repeats the cell placement processing (Step S4) and the routing processing (Step S5) until the routing rule check is passed (Step S6).

From the above description, in the semiconductor chip 1 according to the first embodiment, standard cells included in the second standard cell group are arranged in the second region, the standard cells having a wiring region narrower than that of standard cells included in the first standard cell group, an element region wider than that of the standard cells included in the first standard cell group, and a cell width narrower than that of the standard cells included in the first standard cell group. Accordingly, the semiconductor chip 1 according to the first embodiment can arrange more standard cells within the same width than in a case where all of the first cell tracks are filled with standard cells having the same shape. That is, the semiconductor chip 1 according to the first embodiment can reduce a chip area or perform element placement with higher chip area utilization efficiency.

Further, in the semiconductor chip 1 according to the first embodiment, standard cells included in a third standard cell group are arranged in the third region, the standard cells having a wiring region area smaller than that of standard cells included in the first standard cell group. Accordingly, the semiconductor chip 1 according to the first embodiment can reduce an element area and thereby further reduce a chip area or perform element placement with further improved chip area utilization efficiency.

The autonomous placement and routing program described above includes a group of instructions (or software code) for causing a computer to perform one or more functions described in the embodiment when the program is read by the computer. The program may be stored in a non-transitory computer-readable medium or a tangible storage medium. By way of example and not limitation, the computer-readable medium or the tangible storage medium includes a random-access memory (RAM), a read-only memory (ROM), a flash memory, a solid-state drive (SSD), or other memory techniques, a CD-ROM, a digital versatile disc (DVD), a Blu-ray (registered trademark) disc or other optical disk storage, a magnetic cassette, magnetic tape, magnetic disk storage, or other magnetic storage devices. The program may be transmitted on a transitory computer-readable medium or a communication medium. By way of example and not limitation, the transitory computer-readable medium or the communication medium includes an electrical, optical, acoustic, or other form of propagated signal.

The present invention is not limited to the above-described embodiment, and various modifications may be made without departing from the spirit thereof.

What is claimed is:

1. A semiconductor device comprising:
external pads arranged along sides of a semiconductor chip; and
a plurality of first cell tracks in which standard cells having a first height are arranged in a width direction defined as a first direction in an element placement region interposed between the external pads,
wherein each of the plurality of first cell tracks is provided with
a first region including a center point of the semiconductor chip, and
a second region including a region on an outer peripheral side of the semiconductor chip relative to the first region,
wherein a first standard cell group including a plurality of the standard cells that operate according to different logics is arranged in the first region, and
wherein standard cells included in a second standard cell group are arranged in the second region, the second standard cell group including at least one standard cell having a width narrower than that of the standard cells included in the first standard cell group and operating according to the same logic as the standard cells included in the first standard cell group.

2. The semiconductor device according to claim 1,
wherein the standard cell includes
an element region including a gate contact that connects a gate of a transistor to a wiring arranged in a lowest wiring layer, and an intra-cell inter-element wiring that connects elements arranged within the standard cell and that is arranged in the lowest wiring layer; and
a wiring region that is arranged in the lowest wiring layer and that is defined as a placement region for an inter-cell wiring that connects different standard cells, and
wherein the standard cells included in the second standard cell group have an element region having a height higher than that of the element region of the standard cells included in the first standard cell group and have a wiring region having a height lower than that of the wiring region of the standard cells included in the first standard cell group.

3. The semiconductor device according to claim 2,
wherein the standard cell further includes a power supply wiring portion arranged at an uppermost side in the height direction, and a ground wiring portion arranged at a lowermost side in the height direction, and
wherein two of the wiring regions are arranged so as to interpose the element region in a region interposed between the ground wiring portion and the power supply wiring portion.

4. The semiconductor device according to claim 1, further comprising
second cell tracks in which standard cells having a second height lower than the first height are arranged in the width direction,
wherein the second cell tracks are arranged in a region on an outer peripheral side of the semiconductor chip in the height direction relative to the first cell tracks.

5. The semiconductor device according to claim 4,
wherein a third standard cell group is arranged in the second cell tracks, the third standard cell group including standard cells having a width equal to that of the standard cells included in the first standard cell group and operating according to the same logic as the standard cells included in the first standard cell group.

6. The semiconductor device according to claim 5,
wherein the standard cell includes
an element region including a gate contact that connects a gate of a transistor to a wiring arranged in a lowest wiring layer, and an intra-cell inter-element wiring that connects elements arranged within the standard cell and that is arranged in the lowest wiring layer; and
a wiring region that is arranged in the lowest wiring layer and that is defined as a placement region for an inter-cell wiring that connects different standard cells, and
wherein the standard cells included in the third standard cell group have an element region having a height equal to that of the element region of the standard cells included in the first standard cell group and have a wiring region having a height lower than that of the wiring region of the standard cells included in the first standard cell group.

7. A method of designing a semiconductor device comprising:
floorplan processing for arranging external pads arranged along sides of a semiconductor chip and arranging an element placement region in a region interposed between the external pads;
cell track arrangement processing for arranging, in the element placement region, a plurality of first cell tracks in a height direction in which standard cells having a first height are arranged in a width direction defined as a first direction;
region setting processing for setting a first region including a center point of the semiconductor chip and a second region including a region on an outer peripheral side of the semiconductor chip relative to the first region; and
cell placement processing for arranging a first standard cell group including a plurality of the standard cells that operate according to different logics in the first region and arranging, in the second region, a second standard cell group including at least one standard cell having a width narrower than that of the standard cells included in the first standard cell group and operating according to the same logic as the standard cells included in the first standard cell group,
the method being performed using a computer.
